(19) United States
(12) Patent Application Publication
(10) Pub. No.: US 2015/0326211 A1
(43) Pub. Date: Nov. 12, 2015

(54) VARIABLE DELAY CIRCUIT

(71) Applicant: Rohm Co., Ltd., Kyoto (JP)

(72) Inventors: Kiyoaki Hoshino, Kyoto (JP); Seiichiro Kondo, Kyoto (JP)

(21) Appl. No.: 14/703,980

(22) Filed: May 5, 2015

(30) Foreign Application Priority Data
May 8, 2014 (JP) 2014096881

(51) Int. Cl. H03K 5/01; H02P 27/08; H02M 1/08; H02M 3/156; H03K 3/03; H03K 17/687

(52) U.S. Cl. CPC H03K 5/01; H03K 3/0315; H03K 17/687; H02M 1/08; H02M 3/156; H02P 27/08; H03K 2005/00019

(57) ABSTRACT

A variable delay circuit, includes: an oscillation circuit unit which generates n-phase clock signals, the n-phase clock signals having a same oscillation period and phases of the n-phase clock signals being shifted by 1/n of the oscillation period, wherein n is a natural number equal to or greater than 2; and a delay circuit unit which delays an input signal by using the clock signals to generate an output signal. The delay circuit unit adjusts a delay amount using a phase difference of the clock signals as a minimum variable unit based on a delay amount setting signal.

### CROSS-REFERENCE TO RELATED APPLICATION

This application is based upon and claims the benefit of priority from Japanese Patent Application No. 2014-96881, filed on May 8, 2014, the entire contents of which are incorporated herein by reference.

### TECHNICAL FIELD

The present disclosure relates to a variable delay circuit.

### BACKGROUND

In the field of pulse technology, variable delay circuits that can suitably adjust a delay amount when an output signal is generated by delaying an input signal has been conventionally used for various purposes.

FIG. 18 illustrates a first example of a conventional variable delay circuit 100. In the variable delay circuit 100 of this example, a delay amount is adjusted depending on differences in wiring paths based on combinations of about 2ⁿ signal paths generated by connecting n stages of selectors SL₁ to SLₙ in series. This circuit configuration may adjust a delay amount that has a variable width ranging from 2 to 3 ns by a unit of 10 ps. For example, if a delay amount that has a variable width ranging from 100 ns to 10 μs is adjusted by a unit of 10 ns, the number of necessary stages of selectors is too large to be appropriate. Further, in the usage environment where an ambient temperature or a source voltage changes, a magnitude of a wiring delay is changed, and thus, a delay amount should be periodically checked to replace the selectors so as to regulate the delay amount to be appropriate.

FIG. 19 illustrates a second example of a conventional variable delay circuit 200. In the variable delay circuit 200 of this example, an input signal IN is suitably delayed by using a counter 210 which counts up a clock signal CLK until a count value that depends on a delay amount setting signal DSET is reached, to generate an output signal OUT. Such a circuit configuration needs to use a fast clock signal CLK of 100 MHz when a delay amount that has a variable width ranging from, e.g., 100 ns to 10 μs, is adjusted by a unit of 10 ns. Thus, this configuration may not be employed in the case where such a fast clock signal CLK cannot be used.

FIG. 20 illustrates a third example of a conventional variable delay circuit 300. In the variable delay circuit 300 of this example, 2^{m} delay stages 310, each of which consists of a resistor R, a capacitor C, and a buffer BUF, are connected in series and a selector 320 selects one of delay outputs of the stages to adjust a delay amount without using a fast clock signal. In this circuit configuration, for example, in the case where a selected bit number m for a delay amount is 10, 1024 (=2¹⁰) delay stages 310 are required, increasing the size of the circuit. In addition, there is a problem that a desired delay amount may not be obtained according to characteristic variations of the delay stage 310 (specifically, characteristic variations of metal oxide semiconductor (MOS) transistors constituting the buffers BUF, the resistors R, the capacitors C, and the like).

Further, in a conventional technology in this technical field, a shift clock may be generated by phase-differential shifting (i.e., delaying) a reference clock. However, this is merely a technique of generating a shift clock without using a high frequency signal, rather than adjusting a delay amount applied to an input signal by using a shift clock. Additionally, a plurality of delay elements needs to be used to adjust a phase difference (i.e., delay amount) of a shift clock, and the same problem as that of the third example mentioned above arises.

### SUMMARY

The present disclosure provides some embodiments of a variable delay circuit capable of adjusting a delay amount applied to an input signal by a resolving power (i.e., minimum variable unit) shorter than an oscillation signal of a clock signal.

According to one embodiment of the present disclosure, there is provided a variable delay circuit, including an oscillation circuit unit which generates n-phase clock signals, the n-phase clock signals having a same oscillation period and phases of the n-phase clock signals being shifted by 1/n of the oscillation period, wherein n is a natural number equal to or greater than 2; and a delay circuit unit which delays an input signal by using the clock signals to generate an output signal, wherein the delay circuit unit adjusts a delay amount using a phase difference of the clock signals as a minimum variable unit based on a delay amount setting signal (first configuration).

Further, in the variable delay circuit of the first configuration, the delay circuit unit generates the delay amount by adding a main delay amount, for which the oscillation period of the clock signals is set as a variable unit, and a sub-delay amount, for which a phase difference of the clock signals is set as a variable unit (second configuration).

In addition, in the variable delay circuit of the second configuration, the delay circuit unit comprises a dividing unit which divides the delay amount setting signal by n to generate a quotient signal and a remainder signal, where n is a number of phases of the clock signals, and the main delay amount is set based on the quotient signal and the sub-delay amount is set based on the remainder signal (third configuration).

Moreover, in the variable delay circuit of the third configuration, the delay circuit unit further includes an input latch unit which latches the input signal by using the n-phase clock signals to generate n-phase input latch signals; and an input phase detecting unit which monitors the n-phase input latch signals to generate a phase detection signal which is based on a phase of the input signal, wherein the sub-delay amount is set based on the remainder signal and the phase detection signal (fourth configuration).

Additionally, in the variable delay circuit of the fourth configuration, the delay circuit unit further includes a main delay unit which counts a number of pulses of the clock signals up to a count value depending on the quotient signal and delays at least one of the n-phase input latch signals to generate the main delay signal; a sub-delay unit which latches the main delay signal by using the n-phase clock signals to generate sub-delay signals having a plurality of phases; a selection control unit which generates a selection signal based on the remainder signal and the phase detection signal; and a signal selection unit which outputs one of the sub-delay signals having the plurality of phases as the delay signal based on the selection signal, wherein the delay signal or a logical operation signal of the input signal and the delay signal is outputted as the output signal (fifth configuration).

Furthermore, in the variable delay circuit of the first configuration, the oscillation circuit unit includes a ring oscillator formed as n/2 inverter stages connected in a circular form, and outputs and inverted outputs of each stage of the ring oscillator are outputted as the n-phase clock signals (sixth configuration).

Further, in the variable delay circuit of the sixth configuration, each of the inverter stages includes a capacitor; switches configured to charge and discharge the capacitor; and current sources configured to generate charging/discharging currents of the capacitor (seventh configuration).

In addition, in the variable delay circuit of the second configuration, the oscillation circuit unit includes a ring oscillator formed as n/2 inverter stages connected in a circular form, wherein outputs and inverted outputs of each stage of the ring oscillator are outputted as the n-phase clock signals (eighth configuration).

Moreover, in the variable delay circuit of the eighth configuration, each of the inverter stages includes a capacitor; switches configured to charge and discharge the capacitor; and current sources configured to generate charging/discharging currents of the capacitor (ninth configuration).

Additionally, in the variable delay circuit of the third configuration, the oscillation circuit unit includes a ring oscillator formed as n/2 inverter stages connected in a circular form, wherein outputs and inverted outputs of each stage of the ring oscillator are outputted as the n-phase clock signals (tenth configuration).

Furthermore, in the variable delay circuit of the tenth configuration, each of the inverter stages includes a capacitor; switches configured to charge and discharge the capacitor; and current sources configured to generate charging/discharging currents of the capacitor (eleventh configuration).

Further, in the variable delay circuit of the fourth configuration, the oscillation circuit unit includes a ring oscillator formed as n/2 inverter stages connected in a circular form, wherein outputs and inverted outputs of each stage of the ring oscillator are outputted as the n-phase clock signals (twelfth configuration).

In addition, in the variable delay circuit of the twelfth configuration, each of the inverter stages includes a capacitor; switches configured to charge and discharge the capacitor; and current sources configured to generate charging/discharging currents of the capacitor (thirteenth configuration).

Moreover, in the variable delay circuit of the fifth configuration, the oscillation circuit unit includes a ring oscillator formed as n/2 inverter stages connected in a circular form, wherein outputs and inverted outputs of each stage of the ring oscillator are outputted as the n-phase clock signals (fourteenth configuration).

Additionally, in the variable delay circuit of the fourteenth configuration, each of the inverter stages includes a capacitor; switches configured to charge and discharge the capacitor; and current sources configured to generate charging/discharging currents of the capacitor (fifteenth configuration).

Furthermore, there is provided a switch driving circuit, including a simultaneous OFF time adjusting circuit which adjusts a simultaneous OFF time of an upper switch and a lower switch connected in series between two different electric potentials, wherein the simultaneous OFF time adjusting circuit includes the variable delay circuit of the first configuration as a unit for generating an upper switch control signal and a lower switch control signal by applying a delay to an input signal (sixteenth configuration).

Further, there is provided a switching power supply device comprising the switch driving circuit of the sixteenth configuration (seventeenth configuration).

In addition, there is provided a motor driving device comprising the switch driving circuit of the sixteenth configuration (eighteenth configuration).

In addition, there is provided a switch driving circuit, including a simultaneous OFF time adjusting circuit which adjusts a simultaneous OFF time of an upper switch and a lower switch connected in series between two different electric potentials, wherein the simultaneous OFF time adjusting circuit includes the variable delay circuit of the second configuration as a unit for generating an upper switch control signal and a lower switch control signal by applying a delay to an input signal (nineteenth configuration).

Moreover, there is provided a switch driving circuit, including a simultaneous OFF time adjusting circuit which adjusts a simultaneous OFF time of an upper switch and a lower switch connected in series between two different electric potentials, wherein the simultaneous OFF time adjusting circuit comprises the variable delay circuit of the third configuration as a unit for generating an upper switch control signal and a lower switch control signal by applying a delay to an input signal (twentieth configuration).

### BRIEF DESCRIPTION OF THE DRAWINGS

FIG. 1 is a block diagram illustrating an overall configuration of a variable delay circuit.

FIG. 2 is a circuit diagram illustrating a configuration example of an oscillation circuit unit.

FIG. 3 is a timing chart illustrating an example of a clock generating operation.

FIG. 4 is a block diagram illustrating a configuration example of a delay circuit unit.

FIG. 5 is a block diagram illustrating a configuration example of an input latch unit.

FIG. 6 is a timing chart illustrating an example of an input latch operation.

FIG. 7 is a block diagram illustrating a configuration example of an input phase detecting unit.

FIG. 8 is a table showing a correlation between an input phase and a phase detection signal.

FIG. 9 is a block diagram illustrating a configuration example of a dividing unit.

FIG. 10 is a table showing a correlation between a delay amount setting signal and division outputs.

FIG. 11 is a timing chart illustrating an example of a main delay operation.

FIG. 12 is a block diagram illustrating a configuration example of a sub-delay unit.

FIG. 13 is a timing chart illustrating an example of a sub-delay operation.

FIG. 14 is a signal selection table that a selection control unit refers to.

FIG. 15 is a timing chart illustrating a specific example of a variable delay operation.

FIG. 16 is a block diagram illustrating a configuration example of a power device.

FIG. 17 is a timing chart illustrating an example of a simultaneous OFF time generating operation.

FIG. 18 illustrates a first example of a conventional variable delay circuit.

FIG. 19 illustrates a second example of a conventional variable delay circuit.

FIG. 20 illustrates a third example of a conventional variable delay circuit.

### DETAILED DESCRIPTION

### <Variable Delay Circuit>

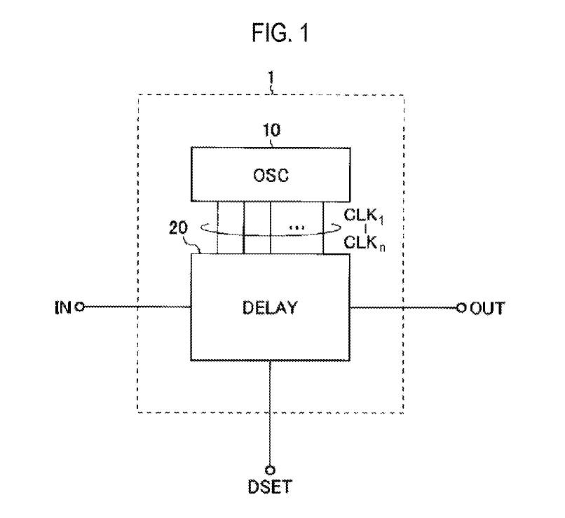

FIG. 1 is a block diagram illustrating an overall configuration of a variable delay circuit 1. The variable delay circuit 1 in this configuration example includes an oscillation circuit unit 10 and a delay circuit unit 20.

The oscillation circuit unit 10 generates n-phase clock signals CLK₁ to CLKₙ which have the same oscillation period T_{osc} and whose phases have been shifted by 1/n of the oscillation period T_{osc} (where n is a natural number equal to or greater than 2).

The delay circuit unit 20 delays an input signal IN by using the clock signals CLK₁ to CLKₙ to generate an output signal OUT. In particular, the delay circuit unit 20 has a function of adjusting a delay amount which is applied to the input signal IN by using a phase difference (i.e., T_{osc}/n) of the clock signals CLK₁ to CLKₙ as a minimum variable unit according to the delay amount setting signal DSET.

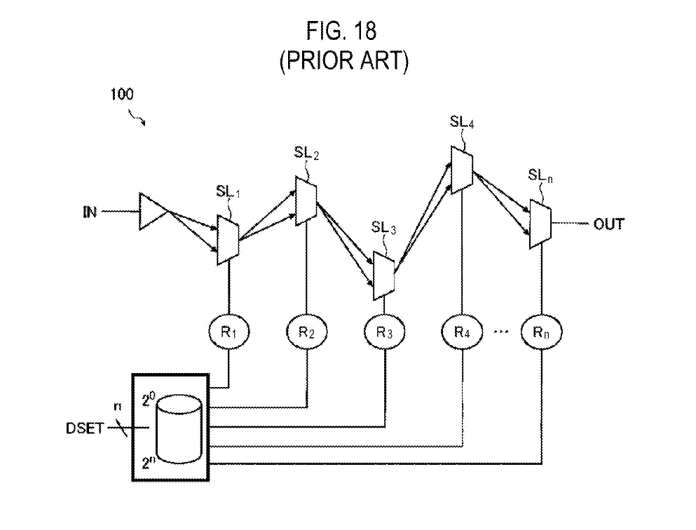

According to the variable delay circuit 1 in this configuration example, unlike the first example of the conventional variable delay circuit 100 (shown in FIG. 18) as described above, for example, even in the case where a delay amount that has a variable width ranging from 100 ns to 10 μs is adjusted by a unit of 10 ns, an excessive number of stages of selectors is not needed. Further, according to the variable delay circuit 1 of this configuration example that does not use a wiring delay, even in the usage environment where an ambient temperature or a source voltage changes, a predetermined delay amount can be obtained, and thus, there is no need to periodically check a delay amount and replace a selector so as to regulate the delay amount to be appropriate.

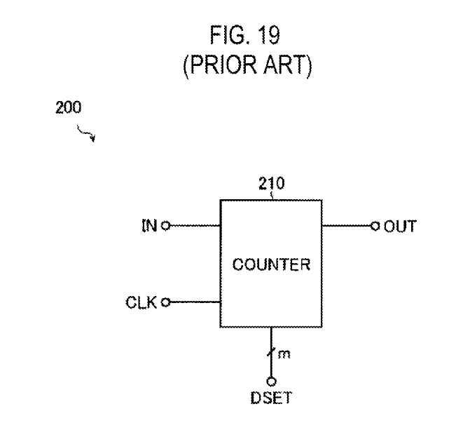

In addition, according to the variable delay circuit 1 in this configuration example, since a delay amount which is applied to the input signal IN can be adjusted with a resolving power (T_{osc}/n) shorter than the oscillation period T_{osc} of the clock signals CLK₁ to CLKₙ, a fast clock signal is not required, unlike the second example of the variable delay circuit 200 (shown in FIG. 19) as described above. Thus, even in the case where a fast clock signal cannot be used due to a limitation in a semiconductor manufacturing process, the delay amount applied to the input signal IN may be adjusted.

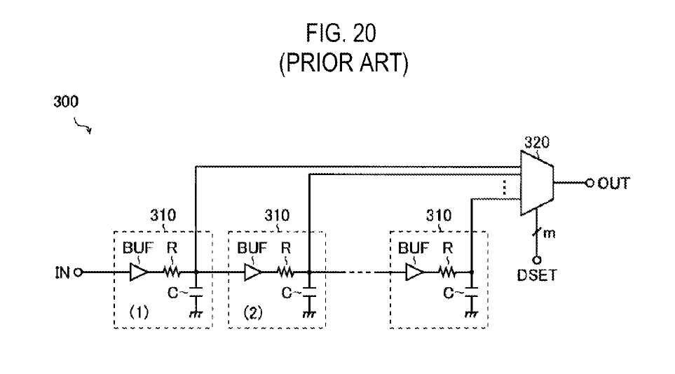

Furthermore, according to the variable delay circuit 1 in this configuration example, unlike the third example of the conventional variable delay circuit 300 (shown in FIG. 20) as described above, even when the number of selected bits of a delay amount increases, an unnecessary increase of a circuit size is not required. Moreover, according to the variable delay circuit 1 of this configuration example that does not use a delay stage, since there is no need to consider a difference in characteristics between delay stages, a predetermined delay amount may be obtained.

Hereinafter, an internal configuration and an operation of each of the oscillation circuit unit 10 and the delay circuit unit 20 will be described in detail.

### <Oscillation Circuit Unit>

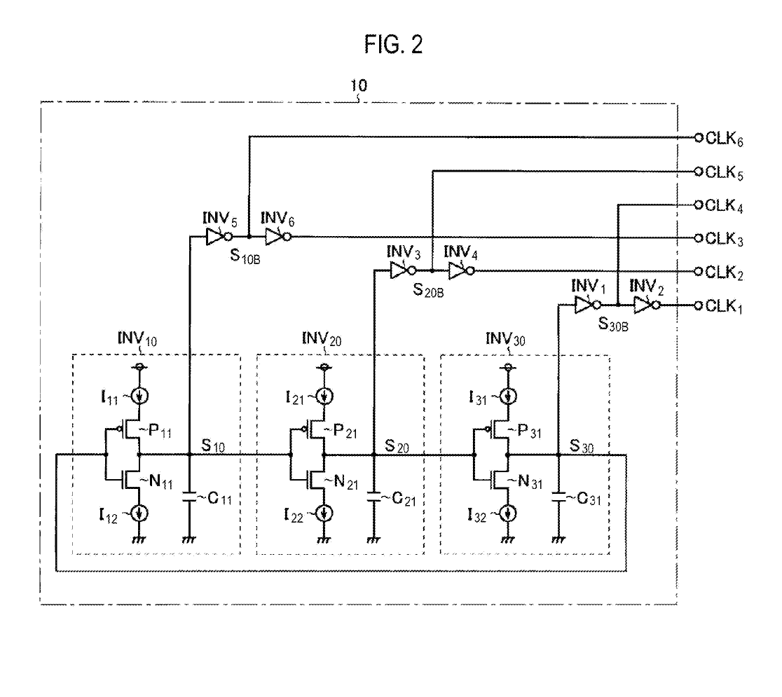

FIG. 2 is a circuit diagram illustrating a configuration example of the oscillation circuit unit 10. The oscillation circuit unit 10 in this configuration example includes a ring oscillator formed with three inverter stages INV₁₀ to INV₃₀ that are connected in a circular form, and output signals S₁₀ to S₃₀ of the respective stages in the ring oscillator and their inverted output signals S_{10B} to S_{30B} are outputted as 6-phase clock signals CLK₁ to CLK₆.

Specifically, the output signal S₃₀ (more specifically, a signal obtained by logically inverting the output signal S₃₀ twice via inverters INV₁ and INV₂) is outputted as the clock signal CLK₁. The output signal S₂₀ (more specifically, a signal obtained by logically inverting the output signal S₂₀ twice via inverters INV₃ and INV₄) is outputted as the clock signal CLK₂. The output signal S₁₀ (more specifically, a signal obtained by logically inverting the output signal S₁₀ twice via inverters INV₅ and INV₆) is outputted as the clock signal CLK₃. The inverted output signal S_{30B} (more specifically, a signal obtained by logically inverting the output signal S₃₀ once via the inverter INV₁) is outputted as the clock signal CLK₄. The inverted output signal S_{20B} (more specifically, a signal obtained by logically inverting the output signal S₂₀ once via the inverter INV₃) is outputted as the clock signal CLK₅. The inverted output signal S_{10B} (more specifically, a signal obtained by logically inverting the output signal S₁₀ once via the inverter INV₅) is outputted as the clock signal CLK₆.

The inverter stage INV₁₀ includes a capacitor C₁₁, a P-channel type MOSFET (field effect transistor) P₁₁, an N-channel type MOSFET N₁₁, and current sources I₁₁ and I₁₂. The transistors P₁₁ and N₁₁ serve as switches for charging and discharging the capacitor C₁₁. The current sources I₁₁ and I₁₂ generate charging and discharging currents for the capacitor C₁₁. A source of the transistor P₁₁ is connected to a power source terminal via the current source I₁₁. Drains of both the transistor P₁₁ and N₁₁ are connected to a first terminal of the capacitor C11 (which is an output terminal of the output signal S₁₀). A source of the transistor N₁₁ is connected to a ground terminal via the current source I₁₂. Gates of both the transistors P₁₁ and N₁₁ are connected to an output terminal of the inverter stage INV₃₀ (which is an output terminal of the output signal S₃₀). A second terminal of the capacitor C₁₁ is connected to ground.

The inverter stage INV₂₀ includes a capacitor C₂₁, a P-channel type MOSFET P₂₁, an N-channel type MOSFET N₂₁, and current sources I₂₁ and I₂₂. The transistors P₂₁ and N₂₁ serve as switches for charging and discharging the capacitor C₂₁. The current sources I₂₁ and I₂₂ generate charging and discharging currents for the capacitor C₂₁. A source of the transistor P₂₁ is connected to a power source terminal via the current source I₂₁. Drains of both the transistor P₂₁ and N₂₁ are connected to a first terminal of the capacitor C₂₁ (which is an output terminal of the output signal S₂₀). A source of the transistor N₂₁ is connected to ground via the current source I₂₂. Gates of both the transistors P₂₁ and N₂₁ are connected to an output terminal of the inverter stage INV₁₀ (which is an output terminal of the output signal S₁₀). A second terminal of the capacitor C₂₁ is connected to ground.

The inverter stage INV₃₀ includes a capacitor C₃₁, a P-channel type MOSFET P₃₁, an N-channel type MOSFET N₃₁, and current sources I₃₁ and I₃₂. The transistors P₃₁ and N₃₁ serve as switches for charging and discharging the capacitor C₃₁. The current sources I₃₁ and I₃₂ generate charging and discharging currents for the capacitor C₃₁. A source of the transistor P₃₁ is connected to a power source terminal via the current source I₃₁. Drains of both the transistors P₃₁ and N₃₁ are connected to a first terminal of the capacitor C₃₁ (which is an output terminal of the output signal S₃₀). A source of the transistor N₃₁ is connected to ground via the current source I₃₂. Gates of both the transistors P₃₁ and N₃₁ are connected to an output terminal of the inverter stage INV₂₀ (which is an output terminal of the output signal S₂₀). A second terminal of the capacitor C₃₁ is connected to ground.

According to the oscillation circuit unit 10 of this configuration example, the 6-phase clock signals CLK₁ to CLK₆ may be generated using the very simple configuration. Further, the oscillation period T_{osc} of the clock signals CLK₁ to CLK₆ may be adjusted by adjusting capacitance values of the capacitors C₁₁ to C₃₁ or charging and discharging current values of the current sources I₁₁ to I₃₁ and I₁₂ to I₃₂.

In addition, although it is illustrated that the oscillation circuit unit 10 of this configuration example generates the 6-phase clock signals CLK₁ to CLK₆, the number of phases of the clock signals is not limited thereto and, for example, in order to generate 10-phase clock signals, five inverter stages may be connected in a ring shape to form a ring oscillator, and outputs and inverted outputs of the respective stages in the ring oscillator may be drawn out. In a generalized manner, in order to generate n-phase clock signals CLK₁ to CLKₙ, n/2 inverter stages may be connected in a ring shape to form a ring oscillator, and outputs and inverted outputs of respective stages in the ring oscillator may be drawn out.

Further, a temperature dependency or a power dependency of the clock signals CLK₁ to CLK₆ generated in the oscillation circuit unit 10 are sufficiently small, relative to a temperature dependency or a power dependency of a wiring delay. Thus, a period difference or duty difference of the clock signals CLK₁ to CLK₆ affecting a final delay amount may be almost negligible.

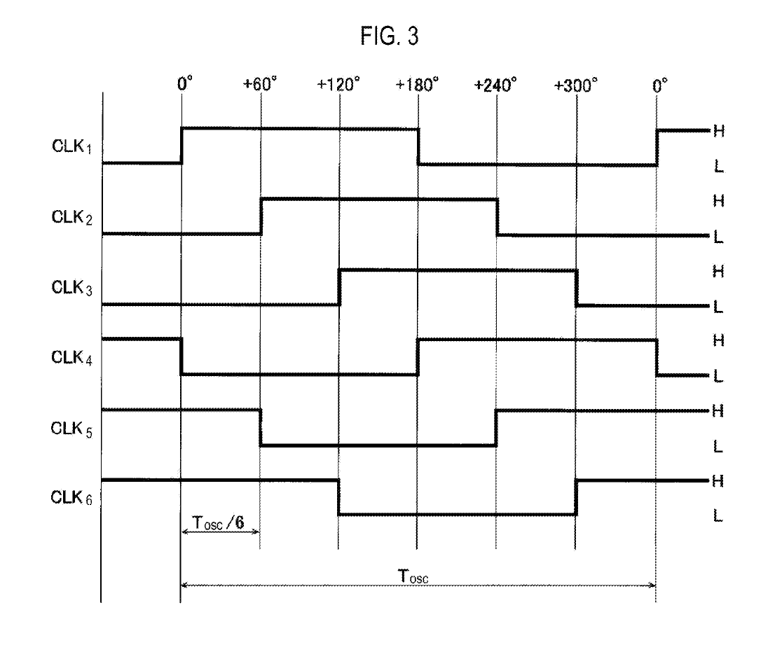

FIG. 3 is a timing chart illustrating an example of a clock generating operation, in which the clock signals CLK₁ to CLK₆ are illustrated in the above order from a top portion of the drawing. As illustrated in FIG. 3, the clock signals CLK₁ to CLK₆ are pulse signals which have the same oscillation period T_{osc} and whose phase is shifted by T_{osc}/6 (phase angle 60°). For example, when the oscillation period T_{osc} is 62.5 ns (corresponding to the oscillation frequency f=16 MHz), the phase difference for the respective clock signals CLK₁ to CLK₆ is 10.417 ns (=62.5 ns/6).

### <Delay Circuit Unit>

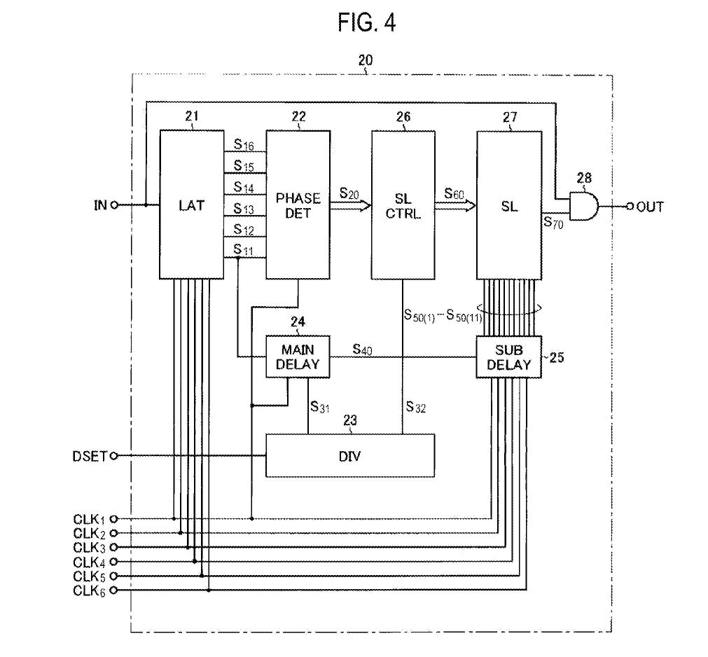

FIG. 4 is a block diagram illustrating a configuration example of the delay circuit unit 20. The delay circuit unit 20 in this configuration example includes an input latch unit 21, an input phase detecting unit 22, a dividing unit (DIV) 23, a main delay unit 24, a sub-delay unit 25, a selection control unit 26, a signal selecting unit 27, and a logical AND operation unit 28.

The input latch unit 21 latches the input signal IN using the clock signals CLK₁ to CLK₆ to generate input latch signals S₁₁ to S₁₆.

The input phase detecting unit 22, in synchronization with the clock signal CLK₁, monitors the input latch signals S₁₁ to S₁₆ to generate a phase detection signal S₂₀ which is based on a phase of the input signal IN.

The dividing unit 23 divides a delay amount setting signal DSET by 6, which is the number of phases of the clock signals CLK₁ to CLK₆, to generate a quotient signal S₃₁ and a remainder signal S₃₂.

The main delay unit 24 counts the number of pulses of the clock signal CLK₁ up to a count value based on the quotient signal S₃₁ (more specifically, a count value obtained by reducing the quotient signal S₃₁ by “1”) and generates a main delay signal S₄₀ by delaying the input latch signal S₁₁.

The sub-delay unit 25 latches the main delay signal S₄₀ by using the clock signals CLK₁ to CLK₆ to generate sub-delay signals S₅₀₍₁₎ to S₅₀₍₁₁₎ having a plurality of phases, more specifically, 11 phases (when generalized, 2n−1 phases).

The selection control unit 26 generates a selection signal S₆₀ based on the remainder signal S₃₂ and the phase detection signal S₂₀.

The signal selecting unit 27 outputs one of the sub-delay signals S₅₀₍₁₎ to S₅₀₍₁₁₎ as a delay signal S₇₀ based on the selection signal S₆₀.

The logical AND operation unit 28 outputs a logical AND signal of the input signal IN and the delay signal S₇₀, as an output signal OUT. Thus, when both the input signal IN and the delay signal S₇₀ rise to a high level, the output signal OUT is of a high level, and one of the input signal IN and the delay signal S₇₀ falls to a low level, the output signal OUT is of a low level. As such, the output signal OUT is a signal obtained by delaying only a rise of the input signal IN. However, when there is no need for the output signal OUT to fall as the input signal IN falls, the logical AND operation unit 28 may be omitted and the delay signal S₇₀ may be outputted as it is, as the output signal OUT.

The delay circuit unit 20 in this configuration example adds a main delay amount (which corresponds to a delay amount applied to the input latch signal S₁₁ in the main delay unit 24) in which the oscillation period T_{osc} of the clock signal CLK₁ is set as a variable unit and a sub-delay amount (which corresponds to a delay amount applied to the main delay signal S₄₀ in the sub-delay unit 25) in which a phase difference T_{osc}/6 of the clock signals CLK₁ to CLK₆ is set as a variable unit to generate a final delay amount (which corresponds to a delay amount applied to the input signal IN). Here, the delay circuit unit 20 sets the main delay amount based on the quotient signal S₃₁, and sets the sub-delay amount based on the remainder signal S₃₂ and the phase detection signal S₂₀. Through this configuration, a delay amount having a variable width ranging from, e.g., 100 ns to 10 μs, may be minutely adjusted by a unit of 10 ns.

### <Input Latch Unit>

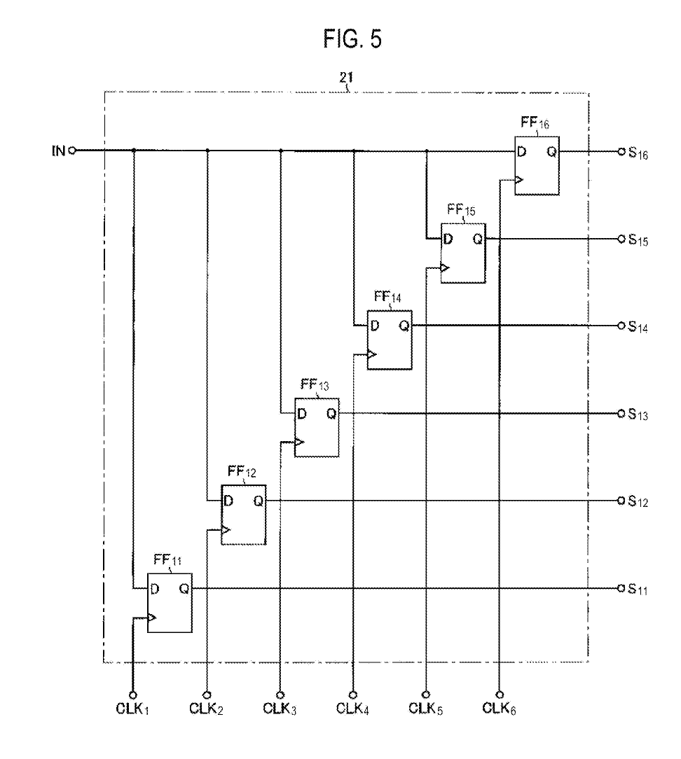

FIG. 5 is a block diagram illustrating a configuration example of the input latch unit 21. The input latch unit 21 of this configuration example includes six D flip-flops FF₁₁ to FF₁₆. Data terminals D of the D flip-flops FF₁₁ to FF₁₆ are all connected to the input terminal of the input signal IN. Clock terminals of the D flip-flops FF₁₁ to FF₁₆ are connected to input terminals of the clock signals CLK₁ to CLK₆, respectively. Output terminals Q of the D flip-flops FF₁₁ to FF₁₆ are connected to output terminals of the input latch signals S₁₁ to S₁₆, respectively.

In the input latch unit 21 of this configuration example, the D flip-flops FF₁₁ to FF₁₆ latch the input signal IN at rising edges of the clock signals CLK₁ to CLK₆ to generate the input latch signals S₁₁ to S₁₆, respectively.

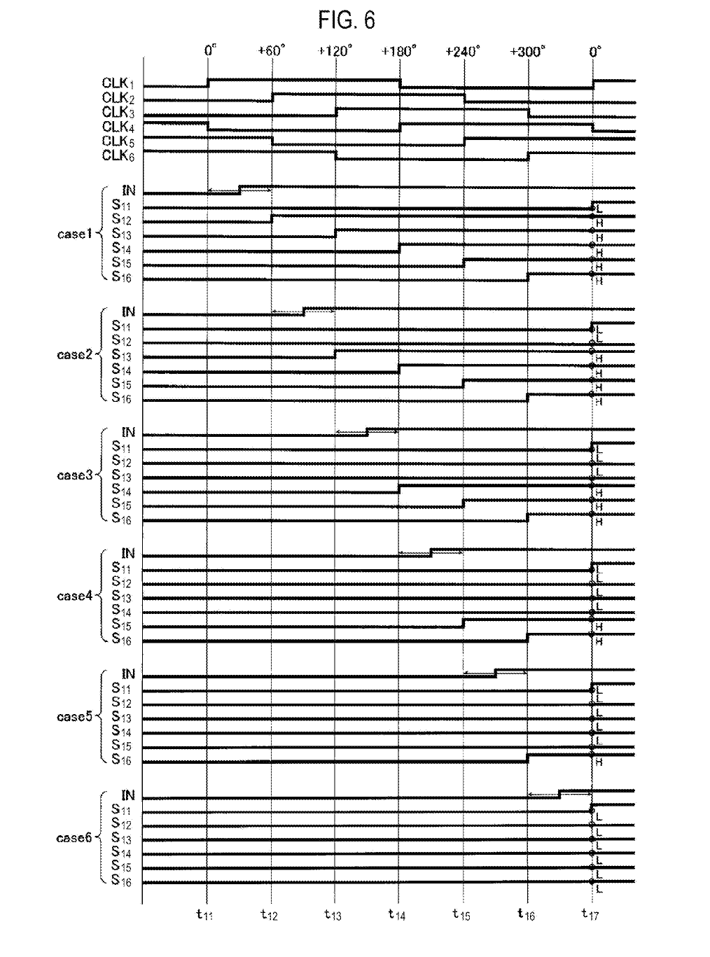

FIG. 6 is a timing chart illustrating an example of an input latch operation in which the clock signals CLK₁ to CLK₆, and the input signals IN and the input latch signals S₁₁ to S₁₆ for respective input phase case 1 to 6 are illustrated in the above order from a top portion of the drawing.

In the example of FIG. 6, the clock signals CLK₁ rises to a high level at time t₁₁, falls to a low level at time t₁₄, and rises again to the high level at time t₁₇. The clock signal CLK₂ rises to a high level at time t₁₂, falls to a low level at time t₁₅, the clock signal CLK₃ rises to a high level at time t₁₃ and falls to a low level at time t₁₆, and the clock signal CLK₄ falls to a low level at time t11, rises to a high level at time t₁₄, and falls again to the low level at time t₁₇. The clock signal CLK₅ falls to a low level at time t₁₂ and rises to a high level at time t₁₅. The clock signal CLK₆ falls to a low level at time t₁₃ and rises to a high level at time t₁₆.

As illustrated in FIG. 6, with respect to the clock signal CLK₁, input phases (phases in which the rising edge of the input signal IN arrives) may be classified into six cases of a first input phase (i.e., case 1) to a sixth input phase (i.e., case 6).

In the first input phase (case 1), a rising edge of the input signal IN arrives in a time duration of t₁₁ to t₁₂. In this case, the input latch signal S₁₁ is of a low level until time t₁₇ (which is the timing at which a rising edge of the clock signal CLK₁ first arrives after an arrival of the rising edge of the input signal IN). The input latch signal S₁₂ is of a low level until the time t₁₂ and a high level from time t₁₂. The input latch signal S₁₃ is of a low level until time t₁₃ and a high level from time t₁₃. The input latch signal S₁₄ is of a low level until time t₁₄ and a high level from time t₁₄. The input latch signal S₁₅ is of a low level until time t₁₅ and a high level from time t₁₅. The input latch signal S₁₆ is of a low level until time t₁₆ and a high level from time t₁₆. Thus, in the first input phase (case 1), only the input latch signal S₁₁ is of a low level and all of the other input latch signals S₁₂ to S₁₆ is of a high level at time t₁₇.

In the second input phase (case 2), a rising edge of the input signal IN arrives in a time duration of t₁₂ to t₁₃. In this case, the input latch signals S₁₁ and S₁₂ are of a low level until time t₁₇. The input latch signal S₁₃ is of a low level until time t₁₃ and a high level from time t₁₃. The input latch signal S₁₄ is of a low level until time t₁₄ and a high level from time t₁₄. The input latch signal S₁₅ is of a low level until time t₁₅ and a high level from time t₁₅. The input latch signal S₁₆ is of a low level until time t₁₆ and a high level from time t₁₆. Thus, in the second input phase (case 2), the input latch signals S₁₁ and S₁₂ are of a low level and all of the other input latch signals S₁₃ to S₁₆ are of a high level at time t₁₇.

In the third input phase (case 3), a rising edge of the input signal IN arrives in a time duration of t₁₃ to t₁₄. In this case, the input latch signals S₁₁ to S₁₃ are of a low level until time t₁₇. The input latch signal S₁₄ is of a low level until time t₁₄ and a high level from time t₁₄. The input latch signal S₁₅ is of a low level until time t₁₅ and a high level from time t₁₅. The input latch signal S₁₆ is of a low level until time t₁₆ and a high level from time t₁₆. Thus, in the third input phase (case 3), the input latch signals S₁₁ to S₁₃ are of a low level and the other input latch signals S₁₄ to S₁₆ are of a high level at time t₁₇.

In the fourth input phase (case 4), a rising edge of the input signal IN arrives in a time duration of t₁₄ to t₁₅. In this case, the input latch signals S₁₁ to S₁₄ are of a low level until time t₁₇. The input latch signal S₁₅ is of a low level until time t₁₅ and a high level from time t₁₅. The input latch signal S₁₆ is of a low level until time t₁₆ and a high level from time t₁₆. Thus, in the fourth input phase (case 4), the input latch signals S₁₁ to S₁₄ are of a low level and the other input latch signals S₁₅ and S₁₆ are of a high level at time t₁₇.

In the fifth input phase (case 5), a rising edge of the input signal IN arrives in a time duration of t₁₅ to t₁₆. In this case, the input latch signals S₁₁ to S₁₅ are of a low level until time t₁₇. The input latch signal S₁₆ is of a low level until time t₁₆ and a high level from time t₁₆. Thus, in the fifth input phase (case 5), the input latch signals S₁₁ to S₁₅ are of a low level and only the input latch signal S₁₆ is of a high level at time t₁₇.

In the sixth input phase (case 6), a rising edge of the input signal IN arrives in a time duration of t₁₆ to t₁₇. In this case, all of the input latch signals S₁₁ to S₁₆ are of a low level until time t₁₇. Thus, in the sixth input phase (case 6), all of the input latch signals S₁₁ to S₁₆ are of a low level at time t₁₇.

In this manner, logical levels of the input latch signals S₁₁ to S₁₆ differ at time t₁₇ depending on the input phases (e.g., case 1 to case 6).

### <Input Phase Detecting Unit>

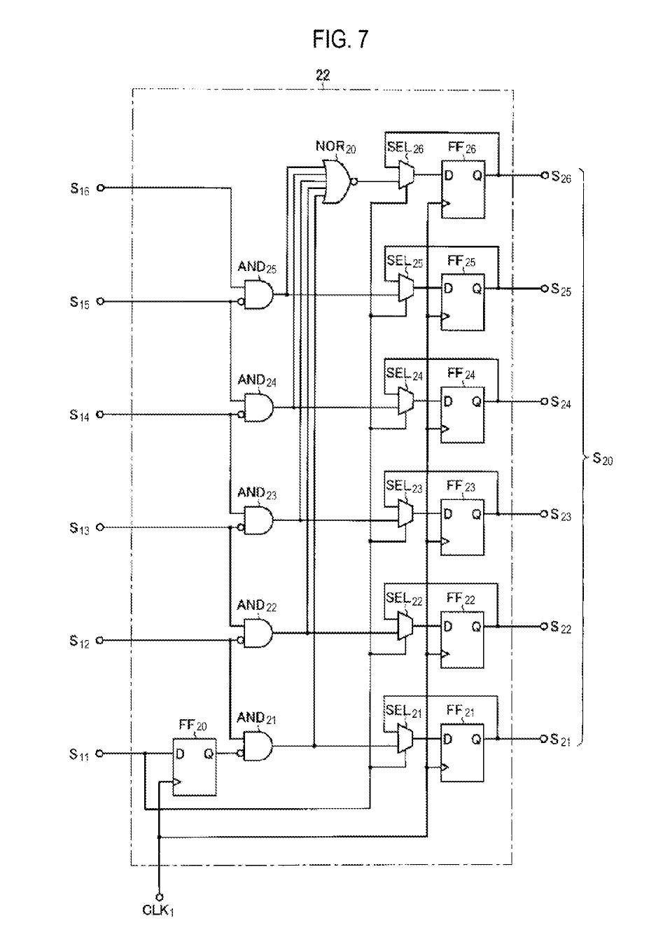

FIG. 7 is a block diagram illustrating a configuration example of the input phase detecting unit 22. The input phase detecting unit 22 in this configuration example includes D flip-flops FF₂₀ to FF₂₆, logical AND operators AND₂₁ to AND₂₅, a logical NOR operator NOR₂₀, and selectors SEL₂₁ to SEL₂₆.

A data terminal D of the D flip-flop FF₂₀ is connected to an input terminal of an input latch signal S₁₁. Clock terminals of the D flip-flops FF₂₀ to FF₂₆ are connected to the input terminal of the clock signal CLK₁. Data terminals D of the D flip-flops FF₂₁ to FF₂₆ are connected to output terminals of the selectors SEL₂₁ to SEL₂₆, respectively. Output terminals Q of the D flip-flops FF₂₁ to FF₂₆ are connected to output terminals of phase detection signals S₂₁ to S₂₆ (which correspond to a first outputted phase detection signal S₂₀), respectively.

A first (inversion) input terminal of the logical AND operator AND₂₁ is connected to the output terminal Q of the D flip-flop FF₂₀. A second (non-inversion) input terminal of the logical AND operator AND₂₁ and a first (inversion) input terminal of the logical AND operator AND₂₂ are connected to the input terminal of the input latch signal S₁₂. A second (non-inversion) input terminal of the logical AND operator AND₂₂ and a first (inversion) input terminal of the logical AND operator AND₂₃ are connected to the input terminal of the input latch signal S₁₃. A second (non-inversion) input terminal of the logical AND operator AND₂₃ and a first (inversion) input terminal of the logical AND operator AND₂₄ are connected to the input terminal of the input latch signal S₁₄. A second (non-inversion) input terminal of the logical AND operator AND₂₄ and a first (inversion) input terminal of the logical AND operator AND₂₅ are connected to the input terminal of the input latch signal S₁₅. A second (non-inversion) input terminal of the logical AND operator AND₂₅ is connected to the input terminal of the input latch signal S₁₆. First to fifth input terminals of the logical NOR operator NOR₂₀ are connected to output terminals of the logical AND operators AND₂₁ to AND₂₅, respectively.

The first input terminals of the selectors SEL₂₁ to SEL₂₆ are connected to output terminals of the logical AND operators AND₂₁ to AND₂₅ and the logical NOR operator NOR₂₀, respectively. Second input terminals of the selectors SEL₂₁ to SEL₂₆ are connected to output terminals Q of the D flip-flops FF₂₁ to FF₂₆, respectively. Control terminals of the selectors SEL₂₁ to SEL₂₆ are connected to the input terminal of the input latch signal S₁₁.

The D flip-flop FF₂₀ latches the input latch signal S₁₁ at a rising edge of the clock signal CLK₁. The D flip-flops FF₂₁ to FF₂₆ latch outputs of the selectors SEL₂₁ to SEL₂₆, respectively, at a rising edge of the clock signal CLK₁ and output the latched results as phase detection signals S₂₁ to S₂₆.

The logical AND operator AND₂₁ performs a logical AND operation on an output signal from the D flip-flop FF₂₀, which is inversion-inputted, and the input latch signal S₁₂, which is non-inversion-inputted, to output a logical AND signal. The logical AND operator AND₂₂ performs a logical AND operation on the input latch signal S₁₂, which is inversion-inputted, and the input latch signal S₁₃, which is non-inversion-inputted, to output a logical AND signal. The logical AND operator AND₂₃ performs a logical AND operation on the input latch signal S₁₃, which is inversion-inputted, and the input latch signal S₁₄, which is non-inversion-inputted, to output a logical AND signal. The logical AND operator AND₂₄ performs a logical AND operation on the input latch signal S₁₄, which is inversion-inputted, and the input latch signal S₁₅, which is non-inversion-inputted, to output a logical AND signal. The logical AND operator AND₂₅ performs a logical AND operation on the input latch signal S₁₅, which is inversion-inputted, and the input latch signal S₁₆, which is non-inversion-inputted, to output a logical AND signal. The logical NOR operator NOR₂₀ receives the outputs from the logical AND operators AND₂₁ to AND₂₅ to output a logical NOR signal.

When the input latch signal S₁₁ is of a low level, the selectors SEL₂₁ to SEL₂₆ select the outputs of the logical AND operators AND₂₁ to AND₂₅ and the logical NOR operator NOR₂₀, respectively. Otherwise, when the input latch signal S₁₁ is of a high level, the selectors SEL₂₁ to SEL₂₆ select the outputs of the D flip-flops FF₂₁ to FF₂₆. As such, in the input phase detecting unit 22 of this configuration example, only when the input latch signal S₁₁ is of a low level, data updating of the phase detection signal S₂₀ is performed, and when the input latch signal S₁₁ is of a high level, data preservation of the phase detection signal S₂₀ is performed.

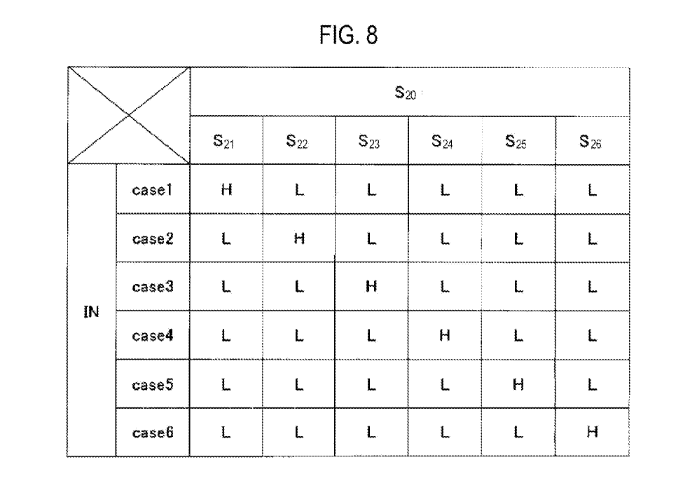

FIG. 8 is a table showing the correlation between the input phases (i.e., case 1 to case 6) of the input signal IN and the phase detection signal S₂₀ (i.e., S₂₁ to S₂₆). As illustrated in FIG. 8, in the first input phase (case 1), only the phase detection signal S₂₁ is of a high level and the phase detection signals S₂₂ to S₂₆ are of a low level. In the second input phase (case 2), only the phase detection signal S₂₂ is of a high level, and the phase detection signals S₂₁ and S₂₃ to S₂₆ are of a low level. In the third input phase (case 3), only the phase detection signal S₂₃ is of a high level, and the phase detection signals S₂₁, S₂₂, and S₂₄ to S₂₆ are of a low level. In the fourth input phase (case 4), only the phase detection signal S₂₄ is of a high level, and the phase detection signals S₂₁ to S₂₃, S₂₅, and S₂₆ are of a low level. In the fifth input phase (case 5), only the phase detection signal S₂₅ is of a high level, and the phase detection signals S₂₁ to S₂₄ and S₂₆ are of a low level. In the sixth input phase (case 6), only the phase detection signal S₂₆ is of a high level, and the phase detection signals S₂₁ to S₂₅ are of a low level. In this manner, only any one of the phase detection signals S₂₁ to S₂₆ is of a high level depending on the six input phases (case 1 to case 6).

Further, the input phase detecting unit 22 of this configuration example is configured to generate the 1-bit phase detection signals S₂₁ to S₂₆ corresponding to the six input phases (case 1 to case 6), respectively, but the configuration of the input phase detecting unit 22 is not limited thereto and, for example, an encoder for generating a 3-bit [2:0] phase detection signal S₂₀ from the input latch signals S₁₁ to S₁₆ may be implemented and an encoded result based on the input phases (case 1 to case 6) may be outputted as the phase detection signal S₂₀, such that “1(001b)” is outputted for the first input phase (case 1), “2(010b)” is outputted for the second input phase (case 2), . . . , and “6(110b)” is outputted for the sixth input phase (case 6).

### <Dividing Unit>

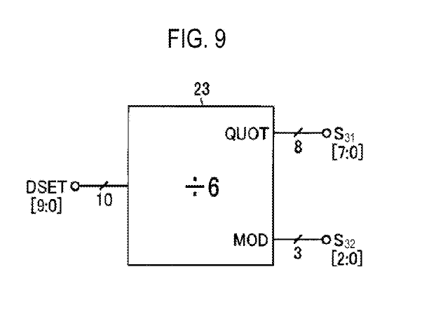

FIG. 9 is a block diagram illustrating a configuration example of the dividing unit 23. The dividing unit 23 of this configuration example divides a 10-bit [9:0] delay amount setting signal DSET by 6, which is the number of phases of the clock signals CLK₁ to CLK₆, to generate an 8-bit [7:0] quotient signal S₃₁ and a 3-bit [2:0] remainder signal S₃₂.

When the delay amount setting signal DSET has 10 bits [9:0], a maximum value of the signal DST is 1023d (3FFh) (hereinafter, “d” and “h” at the ends of the numbers denote a decimal number and a hexadecimal number, respectively, which applies to the following portion in the same manner). Thus, when the delay amount setting signal DSET is divided by 6, which is the number of the phases of the clock signals CLK₁ to CLK₆, the quotient signal S₃₁ ranges from 0d (0h) to 170d (AAh) and the remainder signal S₃₂ ranges 0d (0h) to 5d (5h). Accordingly, it appears that 8 bits (0 to 255) are sufficient for the quotient signal S₃₁ and 3 bits (0 to 7) are sufficient for the remainder signal S₃₂.

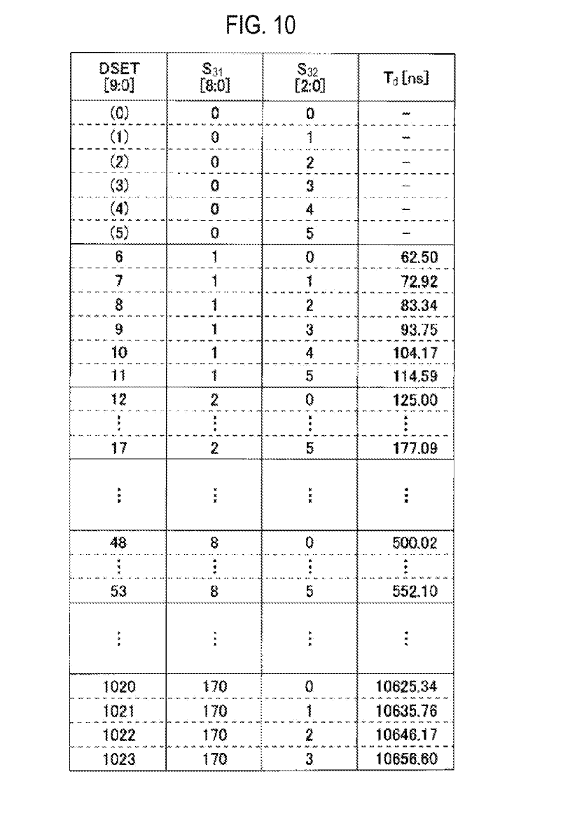

FIG. 10 is a table showing a correlation between the delay amount setting signal DSET, the quotient signal S₃₁, the remainder signal S₃₂, and a delay amount T_{d}[ns]. In FIG. 10, the delay amount setting signal DSET, the quotient signal S₃₁, and the remainder signal S₃₂ are all described with decimal numbers.

For example, in the case where the oscillation period T_{osc} is 62.5 ns (which corresponds to the oscillation frequency f=16 MHz), in the variable delay circuit 1 of this configuration example, the delay amount setting signal DSET is set within a variable range of 6d to 1023d such that the delay amount T_{d} applied to the input signal IN may be suitably adjusted to range from 62.5 ns to 10.6 μs.

For example, in the case where a target value of the delay amount T_{d} is set to 500 ns, 48d (=500 ns/10.417 ns) is inputted as the delay amount setting signal DSET. At this time, the quotient signal S₃₁ is 3d and the remainder signal S₃₂ is 0d.

Further, the main delay unit 24 that receives the quotient signal S₃₁ performs a counting operation on the clock signal CLK₁ up to a count value obtained by reducing the quotient signal S₃₁ by “1” in generating the main delay signal S₄₀ (the details of this operation will be described later). Thus, it is prohibited (or invalidated) to set the delay amount setting signal DSET to 0d to 5d such that the result obtained by reducing the quotient signal S₃₁ by “1” may not be a negative value, namely, such that the quotient signal S₃₁ is not 0d (0h).

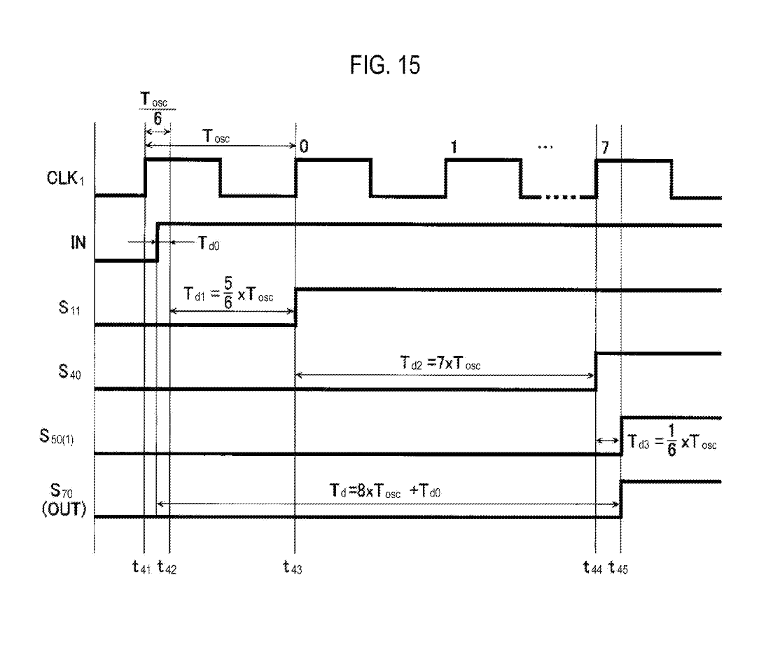

In addition, in a range where the delay amount T_{d} is smaller than 100 ns, an irregular jitter delay time T_{d0} (see FIG. 15 described later) due to the rising timing of the input signal IN cannot be negligible. Thus, it is preferred to set the delay amount setting signal DSET to be within a variable range 10d to 1023d in which the delay amount Td is 100 ns or greater.

### <Main Delay Unit>

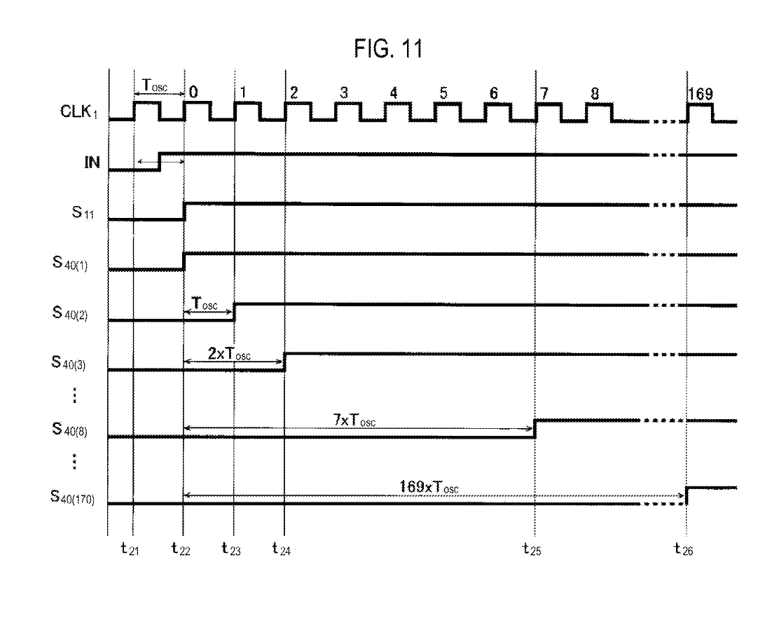

FIG. 11 is a timing chart illustrating an example of a main delay operation, in which the clock signal CLK₁, the input signal IN, the input latch signal S₁₁, and the main delay signal S₄₀ (*) (where “*” is 1 to 170, which is a value that may be taken as the quotient signal S₃₁) are illustrated in the above order from a top portion of the drawing.

In the example of FIG. 11, in a time duration after a rising edge of the clock signal CLK₁ occurs at time t₂₁ and before a next rising edge occurs, the input signal IN rises from a low level to a high level. Thus, the input latch signal S₁₁ is latched to a high level at time t₂₂ at which the rising edge of the clock signal CLK₁ first arrives after the input signal IN has risen to the high level.

In this operation, as mentioned above, the main delay unit 24 delays the input latch signal S₁₁ by counting the number of pulses of the clock signal CLK₁ up to the count value obtained by reducing the quotient signal S₃₁ by “1,” thereby generating the main delay signal S₄₀. Further, the main delay unit 24 may be easily implemented by using the existing variable delay circuit (see FIG. 19) using a counter.

For example, when the quotient signal S₃₁ is 1d, the count value obtained by reducing the quotient signal S₃₁ by “1” is “0.” Thus, the main delay unit 24 outputs the input latch signal S₁₁ as it is, as the main delay signal S₄₀, without counting the number of pulses of the clock signal CLK₁. As such, when the quotient signal S₃₁ is 1d, a main delay signal S₄₀₍₁₎ rises to the high level at time t₂₂, like the input latch signal S₁₁.

In the case where the quotient signal S₃₁ is 2d, the count value obtained by reducing the quotient signal S₃₁ by “1” is “1.” Thus, the main delay unit 24 delays the input latch signal S₁₁ by counting one pulse of the clock signal CLK₁, thereby generating the main delay signal S₄₀. As such, when the quotient signal S₃₁ is 2d, a main delay signal S₄₀₍₂₎ rises to a high level at time t₂₃, at which the number of pulses of the clock signal CLK₁ increases by 1 after the input latch signal S₁₁ rises to the high level at time t₂₂. Here, the main delay signal S₄₀₍₂₎ is a signal that is generated by applying a delay amount corresponding to one period (T_{osc}) of the clock signal CLK to the input latch signal S₁₁.

In the case where the quotient signal S₃₁ is 3d, the count value obtained by reducing the quotient signal S₃₁ by “1” is “2.” As such, the main delay unit 24 delays the input latch signal S₁₁ by counting two pulses of the clock signal CLK₁, thereby generating the main delay signal S₄₀. As such, when the quotient signal S₃₁ is 3d, a main delay signal S₄₀₍₃₎ rises to a high level at time t₂₄, at which the number of pulses of the clock signal CLK₁ increases by 2 after the input latch signal S₁₁ rises to the high level at the time t₂₂. Here, the main delay signal S₄₀₍₃₎ is a signal that is generated by applying a delay amount corresponding to 2 periods (2×T_{osc}) of the clock signal CLK to the input latch signal S₁₁.

Thereafter, in the same manner, when the quotient signal S₃₁ is 8d, a main delay signal S₄₀₍₈₎ is a signal that is generated by applying a delay corresponding to 7 periods (7×T_{osc}) of the clock signal CLK to the input latch signal S₁₁ (see time t₂₅). Also, when the quotient signal S₃₁ is 170d, a main delay signal S₄₀₍₁₇₀₎ is a signal that is generated by applying a delay corresponding to 169 periods (169×T_{osc}) of the clock signal CLK to the input latch signal S₁₁ (see time t₂₆).

Further, the reason for reducing the quotient signal S₃₁ by “1” for determining a count value of the clock signal CLK₁ is because a delay corresponding to one period (T_{osc}) of the maximum clock signal CLK₁ occurs after the input signal IN rises to a high level and before the input latch signal S11 is latched to a high level. Additionally, the corresponding delay amount may vary depending on input phases (i.e., case 1 to case 6), but the variations may be absorbed by adjusting a sub-delay amount applied to the main delay signal S₄₀.

### <Sub-Delay Unit>

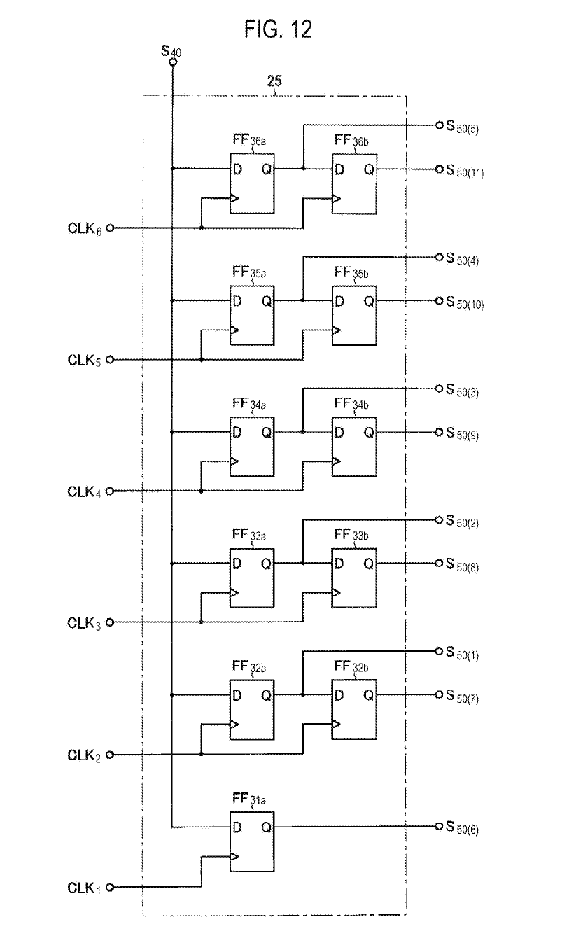

FIG. 12 is a block diagram illustrating a configuration example of the sub-delay unit 25. The sub-delay unit 25 of this configuration example includes D flip-flops FF₃₁a to FF₃₆ₐ and D flip-flops FF_{32b} to FF_{36b}.

Data terminals D of the D flip-flops FF₃₁ₐ to FF₃₆ₐ are connected to the input terminal of the main delay signal S₄₀. Clock terminals of the D flip-flops FF₃₁ₐ to FF₃₆ₐ are connected to the input terminals of the clock signals CLK₁ to CLK₆, respectively. Output terminals Q of the D flip-flops FF₃₁ₐ to FF₃₆ₐ are connected to output terminals of sub-delay signals S₅₀₍₁₎ to S₅₀₍₅₎, respectively. The output terminal Q of the D flip-flop FF₃₁ₐ is connected to an output terminal of the sub-delay signal S₅₀₍₆₎.

Data terminals D of the D flip-flops FF_{32b} to FF_{36b} are connected to output terminals Q of the D flip-flops FF₃₂ₐ to FF₃₆ₐ, respectively. Clock terminals of the D flip-flops FF_{32b} to FF_{36b} are connected to output terminals of sub-delay signals S₅₀₍₇₎ to S₅₀₍₁₁₎, respectively.

The D flip-flops FF₃₁ₐ to FF₃₆ₐ latch the main delay signal S₄₀ at rising edges of the clock signals CLK₁ to CLK₆, respectively. The D flip-flops FF_{32b} to FF_{36b} latch outputs from the D flip-flops FF₃₂ₐ to FF₃₆ₐ at rising edges of the clock signals CLK₂ to CLK₆, respectively.

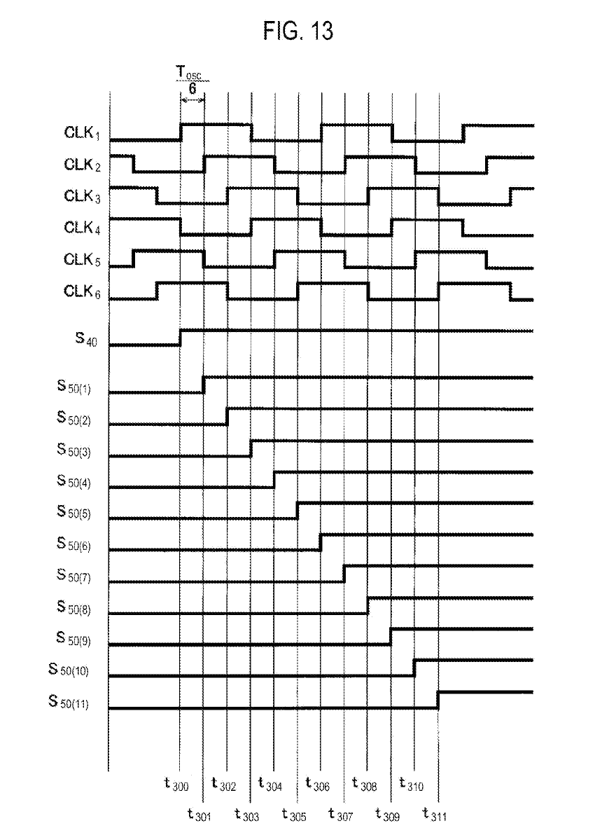

FIG. 13 is a timing chart illustrating an example of a sub-delay operation, in which the clock signals CLK₁ to CLK₆, the main delay signal S₄₀, and the sub-delay signals S₅₀₍₁₎ to S₅₀₍₁₁₎ are illustrated in the above order from a top portion of the drawing.

In FIG. 13, the clock signal CLK₁ rises to a high level at time t₃₀₀, falls to a low level at time t₃₀₃, and rises to the high level at time t₃₀₆. The clock signal CLK₂ rises to a high level at time t₃₀₁, falls to a low level at time t₃₀₄, and rises to the high level at time t₃₀₇. The clock signal CLK₃ rises to a high level at time t₃₀₂, falls to a low level at time t₃₀₅, and rises to the high level at time t₃₀₈. The clock signal CLK₄ falls to a low level at time t₃₀₀, rises to a high level at time t₃₀₃, falls to the low level at a time t₃₀₆, and rises to the high level at a time t₃₀₉. The clock signal CLK₅ falls to a low level at time t₃₀₁, rises to a high level at time t₃₀₄, falls to the low level at time t₃₀₇, and rises to the high level at time t₃₁₀. The clock signal CLK₆ falls to a low level at time t₃₀₂, rises to a high level at time t₃₀₅, falls to the low level at time t₃₀₅, and rises to the high level at time t₃₁₁.

Here, when the main delay signal S₄₀ rises to a high level at time t₃₀₀, the sub-delay signals S₅₀₍₁₎ to S₅₀₍₁₁₎ are latched to high levels at times t₃₀₁ to t₃₁₁, respectively. As such, the rising edges of the sub-delay signals S₅₀₍₁₎ to S₅₀₍₁₁₎ deviate by the phase difference (T_{osc}/6) of the clock signals CLK₁ to CLK₆.

Further, in order to finely adjust a final delay amount based on the remainder signal S₃₂, while absorbing the variations of the delay amount based on the input phases (case 1 to case 6) by adjusting the sub-delay amount applied to the main delay signal S₄₀, 11-phase sub-delay signals S₅₀₍₁₎ to S₅₀₍₁₁₎ are required (whose details will be described later).

### <Selection Control Unit>

As mentioned above, the selection control unit 26 generates a selection signal S₆₀ based on the phase detection signal S₂₀ and the remainder signal S₃₂. Here, the selection control unit 26 refers to a signal selection table in which signal values of the phase detection signal S₂₀ and the remainder signal S₃₂ and contents of the selection signal S₆₀ (indication contents for designating which of the sub-delay signals S₅₀₍₁₎ to S₅₀₍₁₁₎ the signal selecting unit 27 should select as the delay signal S₇₀) are associated with each other.

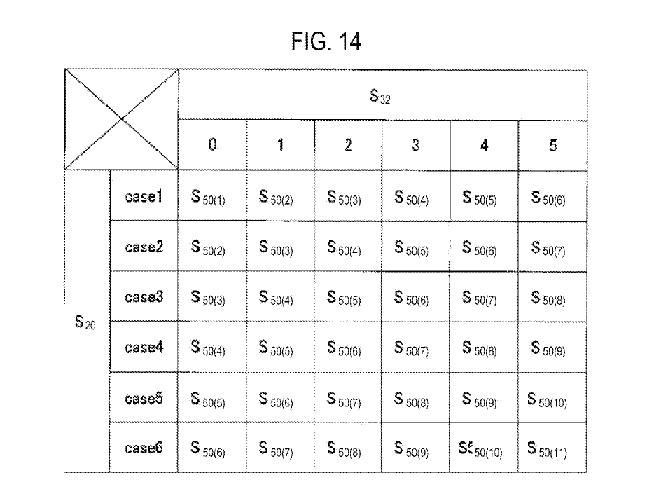

FIG. 14 is an example of a signal selection table that the selection control unit 26 refers to. When the remainder signal S₃₂ is “0,” selection indications of the sub-delay signals S₅₀₍₁₎ to S₅₀₍₆₎ are associated with all of the input phases (case 1 to case 6). When the remainder signal S₃₂ is “1,” selection indications of the sub-delay signals S₅₀₍₂₎ to S₅₀₍₇₎ are associated with all of the input phases (case 1 to case 6). When the remainder signal S₃₂ is “2,” selection indications of the sub-delay signals S₅₀₍₃₎ to S₅₀₍₈₎ are associated with all of the input phases (case 1 to case 6). When the remainder signal S₃₂ is“3,” selection indications of the sub-delay signals S₅₀₍₄₎ to S₅₀₍₉₎ are associated with all of the input phases (case 1 to case 6). When the remainder signal S₃₂ is “4,” selection indications of the sub-delay signals S₅₀₍₅₎ to S₅₀₍₁₀₎ are associated with all of the input phases (case 1 to case 6). When the remainder signal S₃₂ is “5,” selection indications of the sub-delay signals S₅₀₍₆₎ to S₅₀₍₁₁₎ are associated with all of the input phases (case 1 to case 6).

As illustrated in FIG. 14, in order to set appropriate sub-delay amounts for every combination of the phase detection signal S₂₀ and the remainder signal S₃₂, 11-phase sub-delay signals S₅₀₍₁₎ to S₅₀₍₁₁₎ are required.

Further, in the case where the phase detection signal S₂₀ is an encoding signal which becomes values from “1” to “6” in every input phase (case 1 to case 6), the selection signal S₆₀ may be generated by arithmetically operating (or adding) the phase detection signal S₂₀ and the remainder signal S₃₂ without using the signal selection table. For example, in the case where the phase detection signal S₂₀ is “x” (where x is an integer of 1 to 6) and the remainder signal S₃₂ is “y” (where y is an integer of 0 to 5), the selection signal S₆₀ may be generated such that the sub-delay signal S_{50(z)} (where z=x+y) is selected as the delay signal S₇₀.

### Specific Example

FIG. 15 is a timing chart illustrating a specific example (input phase=case 1, delay amount setting signal DSET=48d (delay time T_{d} [target]=500 ns), oscillation period T_{osc}=62.5 ns (oscillation frequency f=16 MHz)) of a variable delay operation, in which the clock signal CKL₁, the input signal IN, the input latch signal S₁₁, the main delay signal S₄₀, the sub-delay signal S₅₀₍₁₎, and the delay signal S₇₀ (a rising timing of a high level is the same as the output signal OUT) are illustrated in the above order from a top portion of the drawing.

In the example of FIG. 15, the input signal IN rises to a high level in a time duration from t₄₁ to t₄₂ (from time t₄₁ at which the clock signal CLK₁ rises to time t₄₂ at which the clock signal CLK₂ (not shown) rises). Further, the input latch signal S₁₁ is latched to a high level at time t₄₃ at which a rising edge of the clock signal CLK₁ first arrives after the input signal IN rises to a high level.

Thus, after the input signal IN rises to a high level and before the input latch signal S₁₁ rises to a high level, without being based on the delay amount setting signal DSET, an irregular jitter delay time T_{d0} (where 0<T_{d0}<T_{osc}/6) that results from the timing at which the input signal IN rises to the high level (from which timing of t₄₁ to t₄₂ the input signal IN rises to a high level) and the latch delay time T_{d1} (in the first input phase case 1, T_{d1}=(5/6)×T_{osc}) depending on the input latch processing occur.

Further, in the case where the delay amount setting signal DSET is 48d, since the quotient signal S₃₁ obtained by dividing 48d by 6, which is the number of phases, is 8d, a count value obtained by the reduction of is “7.” Thus, the main delay unit 24 counts seven pulses of the clock signal CLK₁ and delays the input latch signal S₁₁, thereby generating the main delay signal S₄₀. As such, the main delay signal S₄₀ rises to a high level when the pulse number of the clock signal CLK₁ increased to 7 at time t₄₄, that is, when the main delay time tae (=7×T_{osc}) corresponding to 7 periods of the clock signal CLK, has lapsed after the input latch signal S₁₁ rises to a high level at time t₄₃.

Further, when the delay amount setting signal DSET is 48d, the remainder signal S₃₁ obtained by dividing 48d by 6, which is the number of phases, is 0d. Thus, the selection control unit 26 compares the input result that the phase detection signal S₂₀ is “case 1” and the remainder signal S₃₁ is “0” and the signal selection table of FIG. 14, and instructs the signal selecting unit 27 to select the sub-delay signal S₅₀₍₁₎ as the delay signal S₇₀ (further, the output signal OUT).

Also, the sub-delay signal S₅₀₍₁₎ is latched to a high level when the sub-delay time T_{d3} (=T_{osc}/6) corresponding to a phase difference of the clock signals CLK₁ to CLK₆ has lapsed at time t₄₅ after the main delay signal S₄₀ rises to a high level at time t₄₄. Time t₄₄ and time t₄₅ in FIG. 15 correspond to time t₃₀₀ and t₃₀₁ in FIG. 13, respectively.

Through the sequential signal delay processing described above, a final delay time t_{d} from when the input signal IN rises to a high level until when the output signal OUT rises to a high level is set to a total time of (=8×T_{osc}+T_{d0}) of the jitter delay time T_{d0}, the latch delay time T_{d1} (=(5/6)×T_{osc}), the main delay time T_{d2} (=7×T_{osc}), and the sub-delay time T_{d3} (=T_{osc}/6).

In this manner, in the variable delay circuit 1 of this configuration example, a desired delay time T_{d} (when DSET=48d, T_{d}=500 ns to 510.417 ns) may be set by appropriately adjusting the main delay time T_{d2} and the sub-delay time T_{d3}.

### <Application to Power Supply Device>

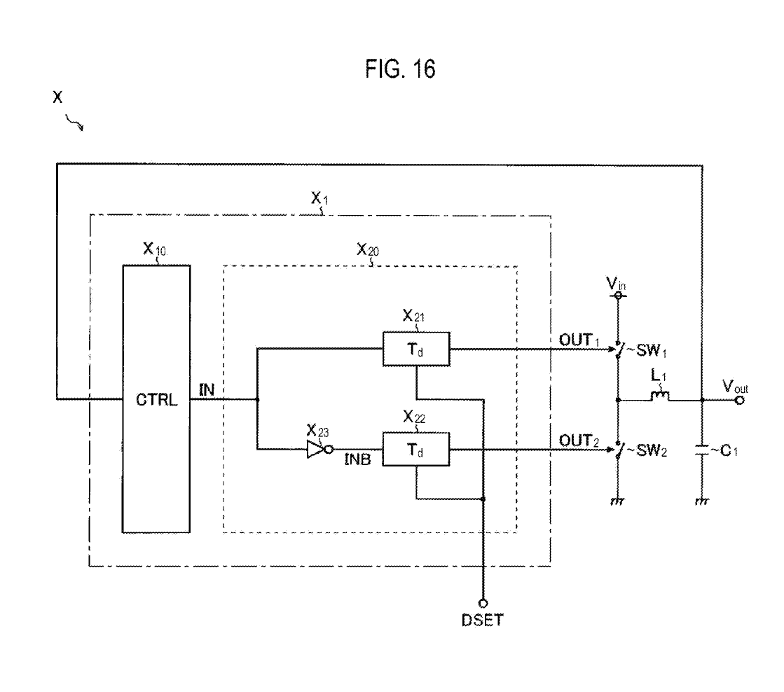

FIG. 16 is a block diagram illustrating a configuration example of a power supply device X. The power supply device X in this configuration example is a switching power supply device X in which an input voltage Vᵢₙ is stepped down to generate an output voltage Vₒᵤₜ, and has a switch driving circuit X₁, an upper switch SW₁, a lower switch SW₂, an inductor L₁, and a capacitor C₁.

The upper switch SW₁ and the lower switch SW₂ are connected in series between an application terminal of the input voltage Vᵢₙ and ground. A connection node between the upper switch SW₁ and the lower switch SW₂ is connected to an output terminal of the output voltage Vₒᵤₜ via the inductor L₁. The output terminal of the output voltage Vₒᵤₜ is connected to ground via the capacitor C₁ and also connected to a feedback input terminal of the switch driving circuit X₁.

The switch driving circuit X₁ includes a control circuit X₁₀ and a simultaneous OFF time adjusting circuit X₂₀. The control circuit X₁₀ drives a pulse of the input signal IN such that an output voltage Vₒ, which is feedback-inputted, is identical to a predetermined target value. The simultaneous OFF time adjusting circuit X₂₀ generates a first output signal OUT₁ and a second output signal OUT₂ from the input signal IN, and outputs the first output signal OUT₁ and the second output signal OUT₂ as control signals of the upper switch SW₁ and the lower switch SW₂, respectively.

The upper switch SW₁ and the lower switch SW₂ are complementarily (exclusively) ON/OFF-controlled based on the first output signal OUT₁ and the second output signal OUT₂. For example, the upper switch SW₁ is turned on when the first output signal OUT₁ is of a high level and turned off when the first output signal OUT₁ is of a low level. Similarly, the lower switch SW₂ is turned on when the second output signal OUT₂ is of a high level and turned off when the second output signal OUT₂ is of a low level.

Through such ON/OFF controlling, a switch voltage in a pulse form is generated in the connection node between the upper switch SW₁ and the lower switch SW₂, and thus, the switch voltage may be rectified and smoothed to step down the input voltage Vᵢₙ to thereby obtain the output voltage Vₒᵤₜ.

Here, the simultaneous OFF time adjusting circuit X₂₀ serves to generate the first output signal OUT₁ and the second output signal OUT₂ from the input signal IN to prepare a simultaneous OFF time T_{d} of the upper switch SW₁ and the lower switch SW₂. Further, the simultaneous OFF time adjusting circuit X₂₀ serves to adjust the simultaneous OFF time T_{d} based on the delay amount setting signal DSET.

In order to implement the foregoing function, the simultaneous OFF time adjusting circuit X₂₀ includes variable delay circuits X₂₁ and X₂₂ and an inverter X₂₃. The variable delay circuit X₂₁ delays a rising edge of the input signal IN by a delay amount based on the delay amount setting signal DSET to generate the first output signal OUT₁. The variable delay circuit X₂₂ delays a rising edge of an inverted input signal IN_{B} by a delay amount based on the delay amount setting signal DSET to generate the second output signal OUT₂. The inverter X₂₃ logically inverts the input signal IN to generate the inverted input signal IN_{B}.

Further, as the variable delay circuits X₂₁ and X₂₂, the variable delay circuit 1 described above may be applied. Here, the variable delay circuits X₂₁ and X₂₂ preferably share the oscillation circuit unit 10.

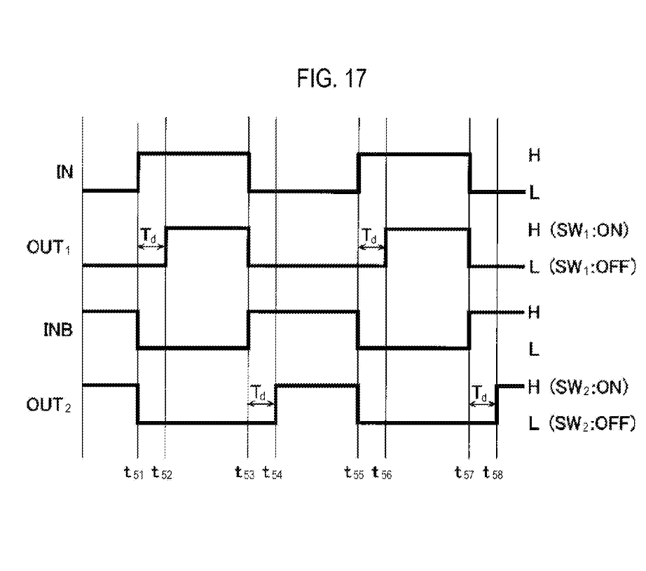

FIG. 17 is a timing chart illustrating an example of a simultaneous OFF time generating operation, in which the input signal IN, the first output signal OUT₁, the inverted input signal IN_{B}, and the second output signal OUT₂ are illustrated in the above order from a top portion of the drawing.

In the example of FIG. 17, the input signal IN rises to a high level at time t₅₁, falls to a low level at time t₅₃, rises to the high level at time t₅₅, and falls to the low level at time t₅₇. Meanwhile, opposite to the input signal IN, the inverted input signal IN_{B} falls to a low level at time t₅₁, rises to a high level at time t₅₃, falls to the low level at time t₅₅, and rises to the high level at time t₅₇.

The first output signal OUT₁ rises to a high level at time t₅₂ delayed by the simultaneous OFF time T_{d} from the time t₅₁ (the timing at which the input signal IN rises), and falls to a low level at time t₅₃ (the timing at which the input signal IN falls). Similarly, the first output signal OUT₁ rises to a high level at time t₅₆ delayed by the simultaneous OFF time T_{d} from the time t₅₅ (the timing at which the input signal IN rises) and falls to a low level at time t₅₇ (the timing at which the input signal IN falls).

The second output signal OUT₂ falls to a low level at time t₅₁ (the timing at which the inverted input signal IN_{B} falls) and rises to a high level at time t₅₄ delayed by the simultaneous OFF time T_{d} from the time t₅₃ (the timing at which the inverted input signal IN_{B} rises). Similarly, the second output signal OUT₂ falls to a low level at time t₅₅ (the timing at which the inverted input signal IN_{B} falls) and rises to a high level at time t₅₈ delayed by the simultaneous OFF time T_{d} from time t₅₅ from time t₅₇ (the timing at which the inverted input signal IN_{B} rises).

Through the signal delay processing described above, when ON/OFF states of the upper switch SW₁ and the lower switch SW₂ are switched, the simultaneous OFF time T_{d} (time duration from t₅₁ to t₅₂, time duration from t₅₃ to t₅₄, time duration from t₅₅ to t₅₆, and time duration from t₅₇ to t₅₈) are inevitably gone through. Thus, generation of a through current through the upper switch SW₁ and the lower switch SW₂ from the application terminal of the input voltage Vᵢₙ to the ground terminal may be prevented in advance.

Further, by applying the foregoing variable delay circuit 1 as each of the variable delay circuits X₂₁ and X₂₂, the simultaneous OFF time T_{d} may be suitably adjusted based on the delay amount setting signal DSET. Thus, it is possible to prevent a through current and enhance efficiency such that the simultaneous OFF time T_{d} can be optimized based on the characteristics of the upper switch SW₁ and the lower switch SW₂.

However, an application subject of the variable delay circuit 1 is not limited to the switch driving circuit X₁ of the power supply device X, and may also be applied to a switch driving circuit of a motor driving device, or the like.

### <Modification of Variable Delay Circuit of Falling Edge Both Edges>

The circuit configuration in which the variable delay circuit delays only the rising edge is illustrated above, and a portion of the foregoing circuit configuration may be modified to realize a variable delay circuit of a falling edge or a variable delay circuit of both edges.

For example, the logical AND operation unit 28 of FIG. 4 may be changed to a logical OR operation unit, and switching control of the selectors SEL₂₁ to SEL₂₆ of FIG. 7 may be changed such that data updating of the phase detection signal S₂₀ is performed when the input latch signal S₁₁ is of a high level, to implement a variable delay circuit of a falling edge.

Further, a variable delay circuit of both edges may be implemented by combining the variable delay circuit of a rising edge and the variable delay circuit of a falling edge. Specifically, the variable delay circuit of both edges may be implemented by connecting the variable delay circuit of a rising edge and the variable delay circuit of a falling edge in series. Here, since a plurality of dividing units 23 overlaps, the dividing units 23 may be integrated.

<Modification without Main Delay Unit>

Further, the configuration in which the main delay unit 24 and the sub-delay unit 25 are separated is illustrated above. In the case where a setting rage of a variable delay amount is narrow (for example, in the case where the delay amount setting signal DSET is 5 bits or less), it may also be configured such that a counting operation by the main delay unit 24 is omitted and the selecting signal S₆₀ is generated directly from the delay amount setting signal DSET.

### <Other Modification>

In addition, the various technical features disclosed in the present disclosure may be differently modified, in addition to the foregoing embodiments, without departing from the spirit and scope of the present disclosure. That is, it is to be considered that the embodiments are not limited and illustrative in all respects, and it is to be understood that the technical scope of the present disclosure is indicated by the accompanying claims, rather than the description of the embodiments, and all changes and modifications that fall within the meaning and scope of equivalents of the claims are included.

The present disclosure can be employed in general application programs, which process a pulse signal (e.g., a pulse width modulation (PWM) signal), in a power supply device, a motor driving device, etc.

According to the present disclosure in some embodiments, it is possible to provide a variable delay circuit capable of adjusting a delay amount given to an input signal by a resolving power shorter than an oscillation signal of a clock signal.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A variable delay circuit, comprising:
an oscillation circuit unit which generates n-phase clock signals, the n-phase clock signals having a same oscillation period and phases of the n-phase clock signals being shifted by 1/n of the oscillation period, wherein n is a natural number equal to or greater than 2; and
a delay circuit unit which delays an input signal by using the clock signals to generate an output signal,
wherein the delay circuit unit adjusts a delay amount using a phase difference of the clock signals as a minimum variable unit based on a delay amount setting signal.

2. The variable delay circuit of claim 1, wherein the delay circuit unit generates the delay amount by adding a main delay amount, for which the oscillation period of the clock signals is set as a variable unit, and a sub-delay amount, for which the phase difference of the clock signals is set as a variable unit.

3. The variable delay circuit of claim 2, wherein the delay circuit unit comprises a dividing unit which divides the delay amount setting signal by n to generate a quotient signal and a remainder signal, where n is a number of phases of the clock signals, and
wherein the main delay amount is set based on the quotient signal and the sub-delay amount is set based on the remainder signal.

4. The variable delay circuit of claim 3, wherein the delay circuit unit further comprises:
an input latch unit which latches the input signal by using the n-phase clock signals to generate n-phase input latch signals; and
an input phase detecting unit which monitors the n-phase input latch signals to generate a phase detection signal which is based on a phase of the input signal, and
wherein the sub-delay amount is set based on the remainder signal and the phase detection signal.

5. The variable delay circuit of claim 4, wherein the delay circuit unit further comprises:
a main delay unit which counts a number of pulses of the clock signals up to a count value depending on the quotient signal and delays at least one of the n-phase input latch signals to generate a main delay signal;
a sub-delay unit which latches the main delay signal by using the n-phase clock signals to generate sub-delay signals having a plurality of phases;
a selection control unit which generates a selection signal based on the remainder signal and the phase detection signal; and
a signal selection unit which outputs one of the sub-delay signals having the plurality of phases as a delay signal based on the selection signal,
wherein the delay signal or a logical operation signal of the input signal and the delay signal is outputted as the output signal.

6. The variable delay circuit of claim 1, wherein the oscillation circuit unit comprises a ring oscillator formed as n/2 inverter stages connected in a circular form, and
wherein outputs and inverted outputs of each stage of the ring oscillator are outputted as the n-phase clock signals.

7. The variable delay circuit of claim 6, wherein each of the inverter stages comprises:
a capacitor;
switches configured to charge and discharge the capacitor; and
current sources configured to generate charging/discharging currents of the capacitor.

8. The variable delay circuit of claim 2, wherein the oscillation circuit unit comprises a ring oscillator formed as n/2 inverter stages connected in a circular form, and
wherein outputs and inverted outputs of each stage of the ring oscillator are outputted as the n-phase clock signals.

9. The variable delay circuit of claim 8, wherein each of the inverter stages comprises:
a capacitor;
switches configured to charge and discharge the capacitor; and
current sources configured to generate charging/discharging currents of the capacitor.

10. The variable delay circuit of claim 3, wherein the oscillation circuit unit comprises a ring oscillator formed as n/2 inverter stages connected in a circular form, and
wherein outputs and inverted outputs of each stage of the ring oscillator are outputted as the n-phase clock signals.

11. The variable delay circuit of claim 10, wherein each of the inverter stages comprises:
a capacitor;
switches configured to charge and discharge the capacitor; and
current sources configured to generate charging/discharging currents of the capacitor.

12. The variable delay circuit of claim 4, wherein the oscillation circuit unit comprises a ring oscillator formed as n/2 inverter stages connected in a circular form, and
wherein outputs and inverted outputs of each stage of the ring oscillator are outputted as the n-phase clock signals.

13. The variable delay circuit of claim 12, wherein each of the inverter stages comprises:
a capacitor;
switches configured to charge and discharge the capacitor; and
current sources configured to generate charging/discharging currents of the capacitor.

14. The variable delay circuit of claim 5, wherein the oscillation circuit unit comprises a ring oscillator formed as n/2 inverter stages connected in a circular form, and
wherein outputs and inverted outputs of each stage of the ring oscillator are outputted as the n-phase clock signals.

15. The variable delay circuit of claim 14, wherein each of the inverter stages comprises:
a capacitor;
switches configured to charge and discharge the capacitor; and
current sources configured to generate charging/discharging currents of the capacitor.

16. A switch driving circuit, comprising:
a simultaneous OFF time adjusting circuit which adjusts a simultaneous OFF time of an upper switch and a lower switch connected in series between two different electric potentials,
wherein the simultaneous OFF time adjusting circuit comprises the variable delay circuit of claim 1 as a unit for generating an upper switch control signal and a lower switch control signal by applying a delay to the input signal.

17. A switching power supply device comprising the switch driving circuit of claim 16.

18. A motor driving device comprising the switch driving circuit of claim 16.

19. A switch driving circuit, comprising:
a simultaneous OFF time adjusting circuit which adjusts a simultaneous OFF time of an upper switch and a lower switch connected in series between two different electric potentials,
wherein the simultaneous OFF time adjusting circuit comprises the variable delay circuit of claim 2 as a unit for generating an upper switch control signal and a lower switch control signal by applying a delay to the input signal.

20. A switch driving circuit, comprising:
a simultaneous OFF time adjusting circuit which adjusts a simultaneous OFF time of an upper switch and a lower switch connected in series between two different electric potentials,
wherein the simultaneous OFF time adjusting circuit comprises the variable delay circuit of claim 3 as a unit for generating an upper switch control signal and a lower switch control signal by applying a delay to the input signal.
